(19) United States
(12) Patent Application Publication
(10) Pub. No.: US 2026/0255850 A1
(43) Pub. Date: Aug. 27, 2026

(54) DISPLAY DEVICE

(71) Applicant: LG Display Co., Ltd., Seoul (KR)

(72) Inventor: HyunSik CHOI, Paju-si (KR)

(21) Appl. No.: 19/425,690

(22) Filed: Dec. 18, 2025

(30) Foreign Application Priority Data
Feb. 26, 2025 (KR) 10-2025-0024970

(51) Int. Cl. H10K 59/80; H10K 59/131; H10K 59/40; H10K 102/00

(52) U.S. Cl. CPC H10K 59/873; H10K 59/131; H10K 59/40; H10K 2102/311

(57) ABSTRACT

A display device including a bendable display panel in which a plurality of sub-pixels are arranged, a support portion overlapping at least a portion of the display panel, a first attachment portion that attaches at least a portion of the display panel to at least a portion of the support portion, and a coating layer overlapping at least a portion of the display panel and disposed on at least a portion of a side surface of the support portion is provided. In this configuration, the display panel is more resistant to cracking when reshaped.

### CROSS REFERENCE TO RELATED APPLICATION

This application claims priority from and the benefit of Korean Patent Application No. 10-2025-0024970, filed on Feb. 26, 2025, which is hereby incorporated by reference for all purposes as if fully set forth herein.

### BACKGROUND

### Field

Embodiments of the invention relate generally to a display device. More particularly, a new way to construct conventionally flat display devices such that they can be bent or assume curved shapes without damage is disclosed.

### Discussion of the Background

As the era of advanced information technology has arrived, the field of display technology, which visually represents electrical information signals, has rapidly developed. In response to this trend, various display devices having excellent characteristics such as reduced thickness, lightweight, and low power consumption have been developed. Specific examples of such display devices include a liquid crystal display (LCD), a plasma display panel (PDP), a field emission display (FED), and an organic light-emitting display (OLED).

As applications for these display devices have multiplied, manufacturers have sought to increase their adaptability and expand the range of physical forms and shapes that displays can assume. New uses continue to arise for displays that can be curved, folded, or rolled. Devices that include displays can be made more compact and portable. An improved range of viewing angles can be supported in a great range of applications. Wearable devices with curved or rolled displays, including watches and clothing items, are becoming more popular. Designers of smartphones, tablets, automotive display screens and medical diagnostic devices are eager to incorporate new bendable display technologies in order to offer consumers electronic devices in forms that are more appealing or practical for their needs.

For example, various components may be mounted in a display device, and structures having various display layouts have been developed to protect such components.

However, the most useful display technologies, including LCD, PDP and OLED technologies, were initially developed to provide flat, non-flexible screens. There remains a need in the art to adapt these display technologies to new market needs for displays that can be curved, folded, or rolled.

The above information disclosed in this Background section is only for understanding of the background of the inventive concepts, and, therefore, it may contain information that does not constitute prior art.

### SUMMARY

Embodiments of the present disclosure meet the above-described need in the art for a display device in which a display panel is bent. Such bending is made practical by a narrow bezel, which is preferred by designers for the modern, minimalist look that it imparts to displays. A narrow bezel also offers the advantage of minimizing any gap between adjacent screens.

Embodiments of the present disclosure may provide a display device including a coating layer that disperses stress generated by bending the display panel.

Additional features of the inventive concepts will be set forth in the description which follows, and in part will be apparent from the description, or may be learned by practice of the inventive concepts.

A display device according to embodiments of the present disclosure may include a bendable display panel in which a plurality of sub-pixels are arranged, a support portion overlapping at least a portion of the display panel, a first attachment portion that attaches at least a portion of the display panel to at least a portion of the support portion, and a coating layer overlapping at least a portion of the display panel and disposed on at least a portion of a side surface of the support portion.

In the display device, a width of the first attachment portion may be smaller than a width of the support portion.

In the display device, the coating layer may be in contact with at least a portion of a lower surface of the support portion and a side surface of the first attachment portion.

The coating layer may be bendable and may bend with a curvature corresponding to a bending curvature of the display panel.

The coating layer may include a first coating layer and a second coating layer, the first coating layer may not be in contact with the support portion, and the second coating layer may be disposed on at least a portion of a side surface of the support portion, at least a portion of a lower surface of the support portion, and a side surface of the first attachment portion.

The display panel may include a touch driving connection line for controlling touch driving of the display panel and a touch planarization layer disposed on the touch driving connection line, and the coating layer may be disposed on the touch planarization layer.

The display panel may include a data connection line for supplying a data voltage to at least one of the plurality of sub-pixels, and the coating layer may overlap with at least a portion of the data connection line.

The display panel may include a driving voltage connection line for supplying a driving voltage to the display panel, and the coating layer may overlap with at least a portion of the driving voltage connection line.

The display device may further comprise a first area in which the touch driving connection line is disposed and a second area in which the data connection line and the driving voltage connection line may be disposed.

The display device may further comprise a data driving circuit that supplies a data voltage, a controller that controls the data driving circuit, a bendable printed circuit board on which the controller is disposed, a shield tape overlapping at least a portion of the support portion, the data driving circuit and the printed circuit board, and a shield can overlapping the controller.

The display device may further comprise a cover glass that protects the display panel and a polarizing layer overlapping the cover glass, wherein a first side surface of the coating layer may be in contact with a side surface of the support portion, and wherein a second side surface of the coating layer may be in contact with a side surface of the polarizing layer.

The display device may further comprise an optical adhesive portion that attaches the cover glass and the polarizing layer, wherein a length of the optical adhesive portion may be greater than a length of the polarizing layer.

The display device may further comprise a buffer portion disposed in an area where the polarizing layer, the optical adhesive portion and the coating layer are adjacent to each other.

The display device may further comprise a second substrate overlapping the polarizing layer and a second attachment portion overlapping the second substrate, wherein the second attachment portion may overlap the first attachment portion and the support portion.

The display device may further comprise a first substrate disposed between the first attachment portion and the second attachment portion, wherein the first substrate may overlap the display panel.

The display device may further comprise a metal plate overlapping the second substrate and the display panel, wherein the second attachment portion may attach the first substrate to the metal plate.

In the display device, the second coating layer may partially overlap with the first coating layer.

In another embodiment, a flexible portion of a display device may comprise a flexible portion of a display panel including a plurality of sub-pixels, a coating layer disposed on the portion of the display panel, a support portion disposed on an edge portion of the display panel portion and directly interfacing with the coating layer along a thickness dimension, a polarizing layer disposed on the coating layer, the polarizing layer being smaller in area than is the coating layer area, a resin material disposed on the coating layer and adjacent to the polarizing layer, a layer of optical clear adhesive disposed on and directly contacting both the polarizing layer and the resin material, and a cover glass disposed on the optical clear adhesive.

A display device may comprise a plurality of such flexible portions.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a system diagram of a display device according to various embodiments of the present disclosure.

FIG. 2 is a plan view of an unbent display device according to various embodiments of the present disclosure.

FIG. 3 is a cross-sectional view of a bent display device according to various embodiments of the present disclosure.

FIG. 4 is a cross-sectional view showing a first substrate BP1, a display panel 110, a first attachment portion PSA1, a support portion SUS, and a coating layer MCL that does not contact the support portion, according to various embodiments of the present disclosure.

FIG. 5 is a cross-sectional view showing a first substrate BP1, a display panel, a first coating layer MCL1, a second coating layer MCL2, and a support portion SUS, according to various embodiments of the present disclosure.

FIG. 6 is a cross-sectional view of a display device in which at least a portion of a display panel is not covered by a coating layer, according to various embodiments of the present disclosure.

FIG. 7 is a plan view showing wirings of a display device disposed between a polarizing layer and a support portion in a state where no coating layer is present, according to various embodiments of the present disclosure.

FIG. 8 is a cross-sectional view showing a first substrate BP1, a display panel 110, a first attachment portion PSA1, a support portion SUS, and a coating layer MCL that is in contact with a side surface and an upper surface of the support portion, according to various embodiments of the present disclosure.

FIG. 9 is a cross-sectional view showing a first substrate BP1, a display panel 110, a first attachment portion PSA1, a support portion SUS, and a coating layer MCL that is in contact with at least a portion of a side surface of the support portion, at least a portion of a lower surface of the support portion, and a side surface of the first attachment portion, according to various embodiments of the present disclosure.

### DETAILED DESCRIPTION

The following describes embodiments of display devices having minimal tendency to crack when reshaped.

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

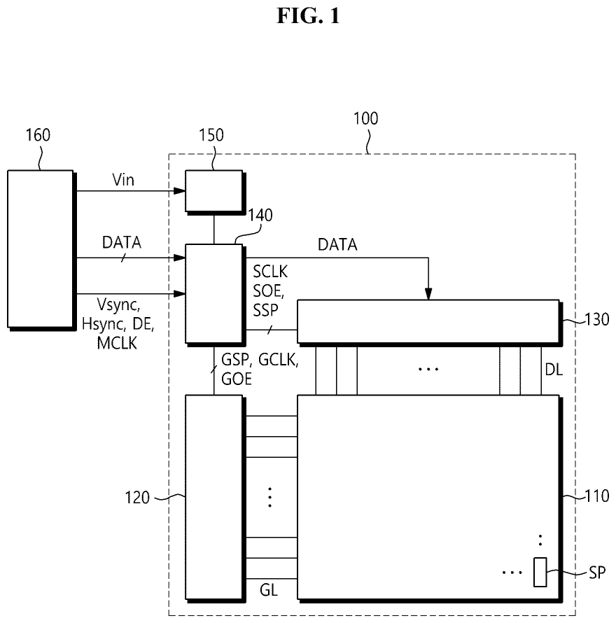

FIG. 1 is a system diagram of a display device 100 according to various embodiments of the present disclosure.

Referring to FIG. 1, the display device 100 according to an embodiment of the present disclosure may include a display panel 110 in which a plurality of gate lines GL and data lines DL are connected and a plurality of sub-pixels SP are arranged in a matrix form, a gate driving circuit 120 that drives the plurality of gate lines GL, a data driving circuit 130 that supplies data voltages through the plurality of data lines DL, a controller 140 that controls the gate driving circuit 120 and the data driving circuit 130, and a power management circuit 150.

The display panel 110 displays an image based on scan signals and light-emission control signals delivered from the gate driving circuit 120 through the plurality of gate lines GL, and data voltages delivered from the data driving circuit 130 through the plurality of data lines DL.

In the case of a liquid crystal display, the display panel 110 may include a liquid crystal layer formed between two substrates and may operate in any known mode such as a twisted nematic (TN) mode, a vertical alignment (VA) mode, an in-plane switching (IPS) mode, or a fringe field switching (FFS) mode. On the other hand, in the case of an organic light-emitting display, the display panel 110 may be implemented in a top emission type, a bottom emission type, or a dual emission type.

The display panel 110 may include a plurality of pixels arranged in a matrix form, and each pixel may include sub-pixels SP of different colors, for example, a white sub-pixel, a red sub-pixel, a green sub-pixel, and a blue sub-pixel. Each sub-pixel SP may be defined by the plurality of data lines DL and the plurality of gate lines GL.

One sub-pixel SP may include a thin film transistor (TFT) formed in a region where one data line DL and one gate line GL intersect, a light-emitting device such as an organic light-emitting diode (OLED) that charges a data voltage, and a storage capacitor that is electrically connected to the light-emitting device to maintain the voltage.

The gate driving circuit 120 is controlled by the controller 140 and controls the driving timing of the plurality of sub-pixels SP by sequentially outputting scan signals to the plurality of gate lines GL disposed in the display panel 110.

In this case, the gate driving circuit 120 may include one or more gate driving integrated circuits (GDICs), and may be disposed only on one side of the display panel 110 or on both sides depending on a driving method. Alternatively, the gate driving circuit 120 may be embedded in a bezel region of the display panel 110 and implemented in a gate-in-panel (GIP) form.

The data driving circuit 130 receives image data DATA from the controller 140, converts the received image data DATA into data voltages in an analog form, and then outputs the data voltages to the respective data lines DL in synchronization with the timing at which scan signals are applied through the gate lines GL. Accordingly, each sub-pixel SP connected to the data lines DL displays a light-emission signal having a luminance corresponding to the data voltage.

Similarly, the data driving circuit 130 may include one or more source driving integrated circuits (SDICs), and the source driving integrated circuits SDICs may be connected to bonding pads of the display panel 110 by a tape automated bonding (TAB) method or a chip-on-glass (COG) method, or may be directly disposed on the display panel 110.

The controller 140 supplies various control signals to the gate driving circuit 120 and the data driving circuit 130 and controls operations of the gate driving circuit 120 and the data driving circuit 130. That is, the controller 140 controls the gate driving circuit 120 to output scan signals according to timing implemented in each frame, and on the other hand, delivers the image data DATA received from outside to the data driving circuit 130.

In this case, the controller 140 receives, from an external host system 160, various timing signals including a vertical synchronization signal (Vsync), a horizontal synchronization signal (Hsync), a data enable (DE) signal, and a main clock (MCLK), together with the image data DATA.

The host system 160 may be any one of a television (TV) system, a set-top box, a navigation system, a personal computer (PC), a home theater system, a mobile device, and a wearable device.

Accordingly, the controller 140 generates a control signal using various timing signals received from the host system 160 and transmits the control signal to the gate driving circuit 120 and the data driving circuit 130.

For example, the controller 140 outputs various gate control signals, including a gate start pulse (GSP), a gate clock (GCLK), and a gate output enable signal (GOE), to control the gate driving circuit 120.

In addition, the controller 140 outputs various data control signals, including a source start pulse (SSP), a source sampling clock (SCLK), and a source output enable signal (SOE), to control the data driving circuit 130.

The display device 100 may include a power management circuit 150 that supplies or controls various voltages or currents to the display panel 110, the gate driving circuit 120, and the data driving circuit 130.

The power management circuit 150 regulates a DC input voltage (Vin) supplied from the host system 160 and generates a driving power for the display panel 110, the gate driving circuit 120, and the data driving circuit 130.

For example, the display device 100 may include a touch driving circuit that supplies a touch driving signal to the display panel 110 and detects a touch sensing signal from the display panel 110, and a touch sensing circuit that senses whether a user touches the display panel 110 and a touch position based on the touch sensing signal detected by the touch driving circuit. The touch driving circuit may be implemented as one or more integrated circuits. The display panel 110 may include a touch driving line to connect the touch driving circuit and a touch electrode. The touch driving line may be referred to as a touch routing wiring.

For example, the display device 100 may include a touch driving connection line electrically connected to the touch driving line. The touch driving connection line may be bonded to or electrically connected to the touch driving circuit.

For example, the touch driving circuit may be implemented in integration with another integrated circuit (e.g., the data driving circuit 130 or the controller 140).

The display device 100 may be any type of display such as a liquid crystal display (LCD), an organic light-emitting display (OLED), or a plasma display panel (PDP).

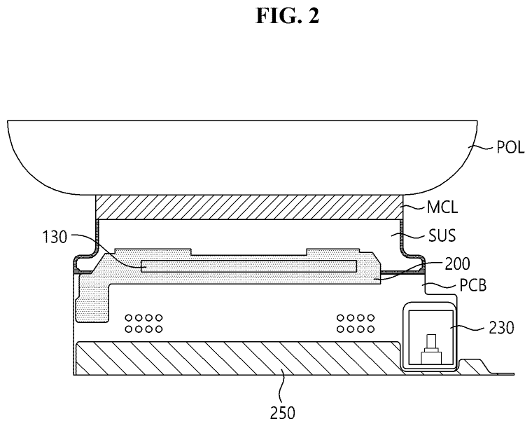

FIG. 2 is a plan view of a non-bending display device 100 according to various embodiments of the present disclosure.

In the following description of FIG. 2, redundant descriptions overlapping with FIG. 1 may be omitted.

Referring to FIG. 2, the display device 100 may include a polarizer POL, a micro coating layer MCL, a support portion SUS, the data driving circuit 130, a shield tape 200, a printed circuit board PCB, a shield can 230, and a protection film 250.

The coating layer MCL may disperse stress generated by bending of the display panel 110 to another component (e.g., the support portion SUS). Accordingly, the occurrence of cracks in the display panel 110 may be minimized. The coating layer MCL may be referred to as a neutral plane. The coating layer MCL may include a resin component.

The polarizer POL may prevent light incident from outside and entering the display panel 110 from being reflected outward. The polarizer POL may prevent deterioration of outdoor visibility of the display panel 110 by preventing the reflection of incident light.

The support portion SUS may distribute the stress generated by bending of the display panel 110 and prevent cracks in the display panel 110. The support portion SUS may include a stainless material.

The shield tape 200 may overlap at least a portion of the support portion SUS, the data driving circuit 130, and the printed circuit board (PCB). For example, the shield tape 200 may be attached to at least a portion of the support portion SUS, the data driving circuit 130, and the printed circuit board (PCB). Accordingly, the components to which the shield tape 200 is attached (e.g., the support portion SUS, the data driving circuit 130, and the printed circuit board PCB) may be protected from external electromagnetic interference or shock. For example, when the touch driving circuit is integrated into the data driving circuit 130, the shield tape 200 may overlap the touch driving circuit.

The printed circuit board (PCB) may mount lines and integrated circuits (e.g., the controller 140 and the power management circuit 150) for driving the display device 100. The printed circuit board (PCB) may be a flexible substrate. The printed circuit board (PCB) may be bendable.

The shield can 230 may protect the integrated circuits from external impact and short circuits. For example, the shield can 230 may overlap at least one integrated circuit among the controller 140, the power management circuit 150, or the touch driving circuit. Alternatively, the shield can 230 may cover at least one integrated circuit among the controller 140, the power management circuit 150, or the touch driving circuit.

The protection film 250 may cover the printed circuit board (PCB). Accordingly, the printed circuit board (PCB) may be protected from external impact and electromagnetic interference.

Hereinafter, a bending-type display device 100 will be described by way of example.

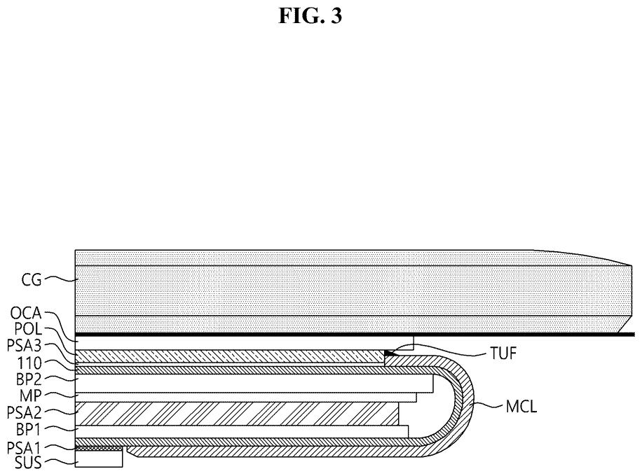

FIG. 3 is a cross-sectional view of a bent display device 100 according to various embodiments of the present disclosure.

In the following description of the components of FIG. 3, descriptions overlapping with those in FIG. 2 may be omitted.

Referring to FIG. 3, the display device 100 may include a cover glass CG, an optical clear adhesive (OCA), a polarizing layer POL, a buffer portion TUF, a first attachment portion PSA1, a second attachment portion PSA2, a third attachment portion PSA3, a display panel 110, a first substrate BP1, a second substrate BP2, a metal plate MP, a supporting portion SUS, and a coating layer MCL.

The cover glass CG may cover the polarizing layer POL and the display panel 110. The cover glass CG may be positioned at the uppermost part of the display device 100 and may thereby protect the display panel 110 from external impact. The cover glass CG may be formed of a plastic material having light-transmitting properties or may be formed of a glass material.

The optical clear adhesive (OCA) may attach the polarizing layer POL to the cover glass CG. The optical clear adhesive OCA may be formed of a transparent material to prevent optical distortion. The length of the optical clear adhesive OCA may be greater than that of the polarizing layer POL. Accordingly, the entire polarizing layer POL may be attached to the cover glass CG. In other words, the optical clear adhesive OCA may leave a margin related to the placement of the polarizing layer POL.

The buffer portion TUF may be disposed in a region adjacent to the optical clear adhesive OCA, the polarizing layer POL, and the coating layer MCL. As described above, due to the length of the optical clear adhesive OCA being greater than that of the polarizing layer POL, a space may be created among the optical clear adhesive OCA, the polarizing layer POL, and the coating layer MCL. The buffer portion TUF may prevent stress or foreign matter intrusion due to the created space. The buffer portion TUF may include a resin component.

The third attachment portion PSA3 may overlap the polarizing layer POL and the display panel 110. For example, the third attachment portion PSA3 may attach the polarizing layer POL to the display panel 110.

The second substrate BP2 may overlap the display panel 110. The second substrate BP2 may support the rigidity of the display panel 110. For example, the second substrate BP2 may overlap the polarizing layer POL.

The metal plate MP may overlap the second substrate BP2 and the display panel 110. The metal plate MP may support the rigidity of the second substrate BP2 and the display panel 110.

The second attachment portion PSA2 may overlap the first substrate BP1 and the metal plate MP. For example, the second attachment portion PSA2 may attach the first substrate BP1 to the metal plate MP. By the second attachment portion PSA2 attaching the first substrate BP1, which overlaps the metal plate MP and the bent display panel 110, stress generated by the bending may be distributed to other components (e.g., the metal plate MP, the second substrate BP2).

The first substrate BP1 may overlap the bent display panel 110.

The first attachment portion PSA1 may overlap the first substrate BP1 and the supporting portion SUS. For example, the first attachment portion PSA1 may attach the first substrate BP1 to the supporting portion SUS.

The first attachment portion PSA1 and the second attachment portion PSA2 may overlap. Accordingly, stress generated by the bending of the display panel 110 may be distributed to the first substrate BP1, the metal plate MP, and the second substrate BP2.

The coating layer MCL may overlap at least a portion of the display panel 110 and may be disposed on side surfaces of the supporting portion SUS and the first attachment portion PSA1. The coating layer MCL may be bendable. The coating layer MCL may be bent to have a curvature corresponding to the bending curvature of the display panel 110.

For example, a first side of the coating layer MCL may contact a side surface of the polarizing layer POL, and a second side of the coating layer MCL may contact a side surface of the supporting portion SUS.

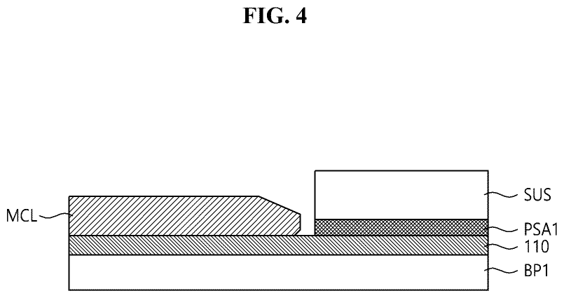

FIG. 4 is a cross-sectional view illustrating the first substrate BP1, the display panel 110, the first attachment portion PSA1, the supporting portion SUS, and the coating layer MCL that is not in contact with the supporting portion SUS, according to various embodiments of the present disclosure.

Referring to FIG. 4, the coating layer MCL may not be in contact with the supporting portion SUS and the first attachment portion PSA1.

Accordingly, at least a portion of the display panel 110 may not be covered by the coating layer MCL.

For example, if the coating layer MCL does not cover at least a portion of the display panel 110, corrosion of wiring in the display panel 110 may occur.

For example, if the coating layer MCL does not contact the side surface of the supporting portion SUS, stress of the display panel 110 may not be transferred. If the stress of the display panel 110 is not transferred, cracks may occur in the display panel 110.

Hereinafter, a method for preventing cracks in the display panel 110 and corrosion of wirings may be illustrated.

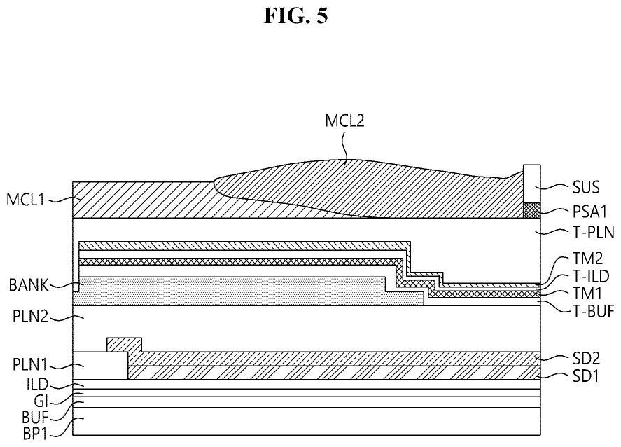

FIG. 5 is a cross-sectional view showing the first substrate BP1, the display panel 110, the first coating layer MCL1, the second coating layer MCL2, and the support portion SUS according to various embodiments of the present disclosure.

In the description of FIG. 5, redundant explanations that overlap with those in FIG. 3 to FIG. 4 may be omitted. The cross-section of FIG. 5 may be a cross-sectional view of a lower bending region in which a touch driving connection line is disposed.

Power lines, signal lines, and touch lines in the display area are connected to connection lines of the bending portion and pass through the bending portion. After passing through the bending portion, they may be connected again to a data connection line, a driving voltage connection line, and a touch driving connection line in order to connect to the data driving circuit 130 and a printed circuit board (PCB).

The cross-section of FIG. 5 may be a cross-sectional view of a region that is connected to the data connection line, the driving voltage connection line, and the touch driving connection line after passing through the bending region.

Referring to FIG. 5, the display device 100 may include the first substrate BP1, the display panel 110, the first coating layer MCL1, the second coating layer MCL2, and the support portion SUS.

The first substrate BP1 may be a single-layer or a multi-layer. When the first substrate BP1 is a multi-layer, the first substrate BP1 may include an intermediate substrate layer. The intermediate substrate layer may be an inorganic insulating layer, but embodiments of the present disclosure are not limited thereto. The intermediate substrate layer may block influences on transistors disposed on the substrate.

The display panel 110 may include a buffer layer BUF, a gate insulating layer GI, an interlayer insulating layer ILD, a first planarization layer PLN1, a second planarization layer PLN2, a first source/drain metal SD1, a second source/drain metal SD2, a bank layer BANK, a touch buffer layer T-BUF, a first touch metal layer TM1, a touch insulating layer T-ILD, a second touch metal layer TM2, and a touch planarization layer T-PLN.

The buffer layer BUF, the gate insulating layer GI, and the interlayer insulating layer ILD may protect or insulate thin film transistors in the display area of the display panel 110. The buffer layer BUF, the gate insulating layer GI, and the interlayer insulating layer ILD may include inorganic materials. For example, the buffer layer BUF, the gate insulating layer GI, and the interlayer insulating layer ILD may be formed of inorganic materials.

For example, the buffer layer BUF may protect other components from moisture penetrating from the substrate.

For example, the gate insulating layer GI may be a layer on which a gate electrode of a thin film transistor is disposed in the display area.

For example, the interlayer insulating layer ILD may be disposed on a gate electrode of a low-temperature polycrystalline silicon (LTPS) transistor or an oxide semiconductor transistor in the display area.

The first planarization layer PLN1 may be disposed between the first source/drain metal SD1 and the second source/drain metal SD2 in the display area.

The second planarization layer PLN2 may be disposed on the second source/drain metal SD2. The second planarization layer PLN2 may protect the second source/drain metal SD2.

The bank layer BANK may be a layer that defines an emission region in the display area.

For example, one of the first source/drain metal SD1 and the second source/drain metal SD2 may include a data connection line for supplying a data voltage, and the other may include a driving voltage connection line for supplying a driving voltage.

For example, the data connection line may be electrically connected to a data line DL. The driving voltage connection line may be electrically connected to a driving voltage line in the display area. For example, the data connection line may be electrically connected to the data driving circuit 130. The driving voltage connection line may be electrically connected to the power management circuit 150.

In other words, the first source/drain metal SD1 and the second source/drain metal SD2 may include or form wirings for driving thin film transistors in the display area.

The touch buffer layer T-BUF may be disposed on the bank layer BANK and the second planarization layer PLN2. For example, the touch buffer layer T-BUF may be disposed on thin film transistors in the display area.

The first touch metal layer TM1 may be disposed on the touch buffer layer T-BUF.

A touch insulating layer T-ILD may be disposed on a first touch metal layer TM1. For example, the touch insulating layer T-ILD may be disposed between a sensor metal layer and a bridge metal layer. For example, the touch insulating layer T-ILD may be an inorganic film.

A second touch metal layer TM2 may be disposed on the touch insulating layer T-ILD.

For example, one of the first touch metal layer TM1 and the second touch metal layer TM2 may be the sensor metal layer, and the other may be the bridge metal layer. The sensor metal layer and the bridge metal layer may be referred to as touch driving connection lines. Alternatively, the sensor metal layer and the bridge metal layer may include the touch driving connection lines.

The touch planarization layer T-PLN may be disposed on the second touch metal layer TM2. The touch planarization layer T-PLN may protect the first touch metal layer TM1 and the second touch metal layer TM2. In other words, the touch planarization layer T-PLN may be disposed on the touch driving connection lines.

The coating layer MCL may include a first coating layer MCL1 and a second coating layer MCL2. The first coating layer MCL1 and the second coating layer MCL2 may be disposed on the touch planarization layer T-PLN. In other words, the coating layer MCL may overlap the touch driving connection lines, the data connection lines, and the driving voltage connection lines, and may protect them from external impact.

The first coating layer MCL1 may overlap a bank BANK and a first planarization layer PLN1 disposed in a lower bending region, and may not overlap the second coating layer MCL2. A touch electrode on the first planarization layer PLN1 and the bank BANK may be connected to a touch pad portion and electrically connected to a printed circuit board (PCB). The touch pad portion may include the touch electrode and a gate electrode or a source or drain electrode forming a transistor of a display area.

The touch electrode forming the touch pad and the gate electrode or the source or drain electrode may be connected through a contact hole. In this case, when there are many insulating layers between the touch electrode and the gate electrode or the source or drain electrode, the depth of the contact hole may become large. As the depth of the contact hole increases, it may be difficult to connect the touch electrode and the gate electrode or the source or drain electrode.

Accordingly, intermediate insulating layers (e.g., the bank layer BANK and the first planarization layer PLN1) may be cut before the touch pad portion. For example, the bank layer BANK or the first planarization layer PLN1 may be disposed in at least a portion of the lower bending region.

For example, one end of the first coating layer MCL1 may not be in contact with a support SUS. The other end of the first coating layer MCL1 may be in contact with the polarizer POL.

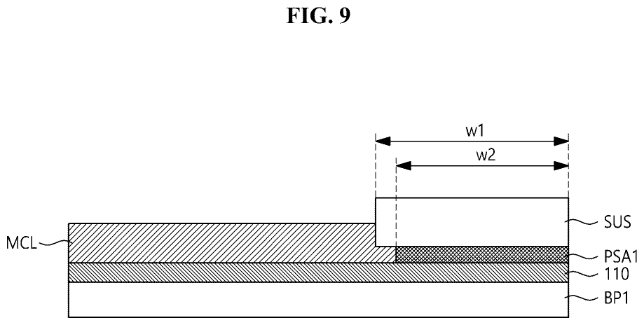

For example, the second coating layer MCL2 may be in contact with the support SUS. For example, the second coating layer MCL2 may be disposed on at least a portion of a side surface of the support SUS, at least a portion of a lower surface of the support SUS, and a side surface of the first adhesive member PSA1. A detailed description thereof may be illustrated in the description of FIG. 9.

For example, by applying the first coating layer MCL1 first and then applying the second coating layer MCL2, the coating layer MCL may be precisely applied around the support SUS. Accordingly, it is possible to minimize a problem in which the coating layer MCL fails to cover at least a portion of the display panel 110. The second coating layer MCL2 may be partially overlapped with the first coating layer MCL1 to allow the coating layer to be sufficiently applied over the display panel 110.

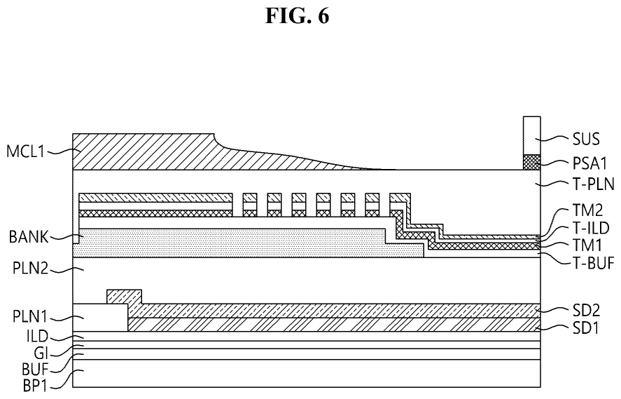

FIG. 6 is a cross-sectional view of the display device 100 in which at least a portion of the display panel 110 is not covered by the coating layer MCL, according to various embodiments of the present disclosure.

In the description of FIG. 6, the descriptions that overlap with those in FIG. 5 may be omitted.

Referring to FIG. 6, in a region where the coating layer MCL does not cover the display panel 110 or is not sufficiently applied, the first touch metal layer TM1, the second touch metal layer TM2, and the touch insulating layer T-ILD may be corroded.

Accordingly, the touch driving connection lines may be corroded or a defect may occur.

For example, in a region where the coating layer MCL does not cover the display panel 110 or is thinner than other regions, the display panel 110 may not be protected from external impact.

For example, when the coating layer MCL is not connected to the support SUS, stress generated by the bending of the display panel 110 may not be dispersed to the support SUS. Accordingly, a crack may occur in the display panel 110.

For example, when a crack occurs in the display panel 110, corrosion may also occur in the first source/drain metal SD1 and the second source/drain metal SD2.

Hereinafter, lines of the display device 100 may be illustrated in a state where no coating layer MCL is present.

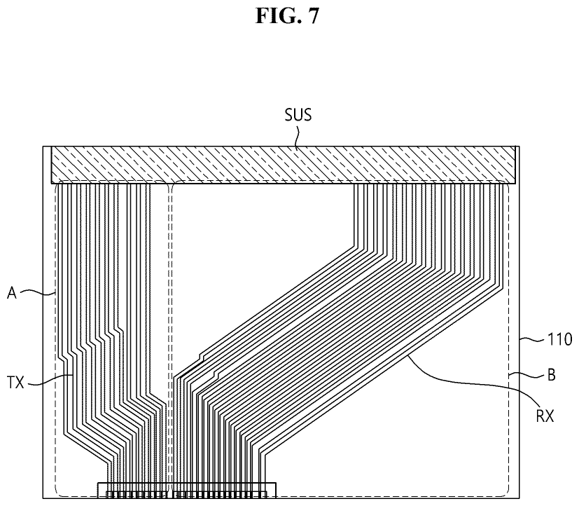

FIG. 7 is a plan view illustrating wirings of the display device 100 disposed between the polarizer POL and the support SUS in a state where no coating layer MCL is present, according to various embodiments of the present disclosure.

Referring to FIG. 7, the display device 100 may include the display panel 110 and the support SUS.

The display panel 110 may include a plurality of first lines TX disposed in a first region A, and a plurality of second lines RX disposed in a second region B. Accordingly, a short between the first lines TX and the second lines RX, to which different voltages are applied, may be prevented.

The first lines TX may include touch driving connection lines for controlling touch driving of the display panel 110.

The second lines RX may include at least one of a data connection line for supplying a data voltage to subpixels SP of the display panel 110, and a driving voltage connection line for supplying a driving voltage to the display panel 110.

A high voltage may be applied to the touch driving connection lines. When a high voltage is applied, the lines may be vulnerable to corrosion or failure. If at least a portion of the display panel 110 is not covered by the coating layer MCL, the touch driving connection lines may be corroded. If the touch driving connection lines are corroded, a failure in touch driving may occur.

For example, if at least a portion of the display panel 110 is not covered by the coating layer MCL, the data connection lines or the driving voltage connection lines may be corroded. If the data connection lines or the driving voltage connection lines are corroded, a failure in image display of the display panel 110 may occur.

Hereinafter, the display device 100 having a structure in which the display panel 110 is covered will be described as an example.

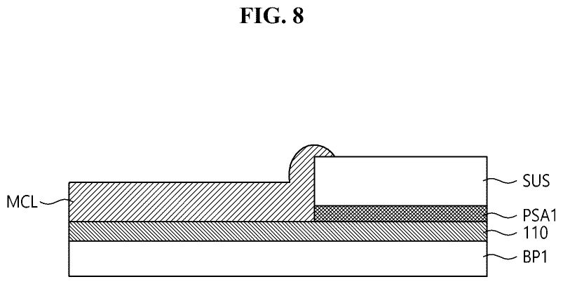

FIG. 8 is a cross-sectional view illustrating the first substrate BP1, the display panel 110, a first attachment portion PSA1, the support SUS, and the coating layer MCL in contact with a side surface and an upper surface of the support SUS according to various embodiments of the present disclosure.

In the following description of FIG. 8, overlapping descriptions with those in FIG. 4 to FIG. 6 may be omitted.

Referring to FIG. 8, for example, when the coating layer MCL covers the upper surface of the support SUS, it may be difficult to fasten other components of the display device 100.

Hereinafter, a structure for precisely applying the coating layer MCL will be described as an example.

FIG. 9 is a cross-sectional view illustrating the first substrate BP1, the display panel 110, the first attachment portion PSA1, the support SUS, and the coating layer MCL in contact with at least a portion of a side surface of the support SUS, at least a portion of a lower surface of the support SUS, and a side surface of the first attachment portion PSA1 according to various embodiments of the present disclosure.

In the following description of FIG. 9, overlapping descriptions with those in FIG. 4 to FIG. 8 may be omitted.

Referring to FIG. 9, the first attachment portion PSA1 may attach at least a portion of the support SUS to the display panel 110.

For example, a first width W1 of the support SUS may be greater than a second width W2 of the first attachment portion PSA1. Accordingly, the coating layer MCL may be in contact with at least a portion of the side surface of the support SUS, at least a portion of the lower surface of the support SUS, and the side surface of the first attachment portion PSA1.

The first attachment portion PSA1 may be formed by a pull-back process. For example, the first attachment portion PSA1 may first be formed with the same width as the support SUS, and then at least a portion of the first attachment portion PSA1 may be etched or removed. Accordingly, the width of the first attachment portion PSA1 may be precisely adjusted. In other words, when the first attachment portion PSA1 is precisely adjusted, a space for placing the coating layer MCL may be precisely adjusted.

As the first width W1 is greater than the second width W2, a portion of the coating layer MCL may be inserted under the support SUS. As a portion of the coating layer MCL is inserted downward, a phenomenon in which the coating layer MCL covers the upper surface of the support SUS may be minimized.

In other words, as an excess portion of the coating layer MCL is inserted into an adjacent region of the display panel 110, the support SUS, and the first attachment portion PSA1, a phenomenon in which the coating layer MCL fails to cover at least a portion of the display panel 110 or covers the upper surface of the support SUS may be minimized.

Accordingly, a phenomenon in which the coating layer MCL on the upper surface of the support SUS interferes with the fastening of other components, causes failure in the wiring of the display device 100, or causes cracks in the display panel 110 may be minimized.

The display device according to embodiments of the present disclosure may be described as follows.

A display device according to embodiments of the present disclosure may include a bendable display panel in which a plurality of sub-pixels are disposed, a support portion overlapping at least a part of the display panel, a first attachment portion that attaches at least a part of the display panel and at least a part of the support portion, and a coating layer overlapping at least a part of the display panel and disposed on at least a part of a side surface of the support portion.

A width of the first attachment portion may be smaller than a width of the support portion.

The coating layer may contact at least a part of a lower surface of the support portion and a side surface of the first attachment portion.

The coating layer may be bendable and may be bent with a curvature corresponding to a bending curvature of the display panel.

The coating layer may include a first coating layer and a second coating layer.

The first coating layer may not contact the support portion.

The second coating layer may be disposed on at least a part of the side surface of the support portion, at least a part of the lower surface of the support portion, and a side surface of the first attachment portion.

The display panel may include a touch driving connection line for controlling touch driving of the display panel and a touch planarization layer disposed on the touch driving connection line.

The coating layer may be disposed on the touch planarization layer.

The display panel may include a data connection line for supplying a data voltage to at least one of the plurality of sub-pixels.

The coating layer may overlap at least a part of the data connection line.

The display panel may include a driving voltage connection line for supplying a driving voltage to the display panel.

The coating layer may overlap at least a part of the driving voltage connection line.

The display panel may include a first area in which the touch driving connection line is disposed, and a second area in which the data connection line and the driving voltage connection line are disposed.

The display device may include a data driving circuit for supplying a data voltage, a controller for controlling the data driving circuit, a bendable printed circuit board on which the controller is disposed, a shield tape overlapping at least a part of the support portion, the data driving circuit, and the printed circuit board, and a shield can overlapping the controller.

The display device may include a cover glass protecting the display panel and a polarizing layer overlapping the cover glass.

A first side surface of the coating layer may contact a side surface of the support portion.

A second side surface of the coating layer may contact a side surface of the polarizing layer.

The display device may include an optical adhesive portion attaching the cover glass and the polarizing layer.

A length of the optical adhesive portion may be greater than a length of the polarizing layer.

The display device may include a buffer portion disposed in an area where the polarizing layer, the optical adhesive portion, and the coating layer are adjacent to one another.

The display device may further include a second substrate overlapping the polarizing layer and a second attachment portion overlapping the second substrate.

The second attachment portion may overlap the first attachment portion and the support portion.

The display device may include a first substrate disposed between the first attachment portion and the second attachment portion.

The first substrate and the display panel may overlap each other.

According to embodiments of the present disclosure, a display device may be provided in which the display panel is not exposed between the coating layer and the support portion.

According to embodiments of the present disclosure, a display device may be provided in which the coating layer does not fail to cover the display panel or is prevented from being disposed on an upper surface of the support portion, thereby optimizing the manufacturing process.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a bendable display panel in which a plurality of sub-pixels are arranged;
a support portion overlapping at least a portion of the display panel;
a first attachment portion that attaches at least a portion of the display panel to at least a portion of the support portion; and
a coating layer overlapping at least a portion of the display panel and disposed on at least a portion of a side surface of the support portion.

2. The display device according to claim 1, wherein a width of the first attachment portion is smaller than a width of the support portion.

3. The display device according to claim 2, wherein the coating layer is in contact with at least a portion of a lower surface of the support portion and a side surface of the first attachment portion.

4. The display device according to claim 3, wherein the coating layer is bendable and bends with a curvature corresponding to a bending curvature of the display panel.

5. The display device according to claim 1,
wherein the coating layer includes a first coating layer and a second coating layer,
wherein the first coating layer is not in contact with the support portion, and
wherein the second coating layer is disposed on at least a portion of a side surface of the support portion, at least a portion of a lower surface of the support portion, and a side surface of the first attachment portion.

6. The display device according to claim 1, wherein the display panel includes a touch driving connection line for controlling touch driving of the display panel and a touch planarization layer disposed on the touch driving connection line, and wherein the coating layer is disposed on the touch planarization layer.

7. The display device according to claim 6,
wherein the display panel includes a data connection line for supplying a data voltage to at least one of the plurality of sub-pixels, and
wherein the coating layer overlaps with at least a portion of the data connection line.

8. The display device according to claim 7,
wherein the display panel includes a driving voltage connection line for supplying a driving voltage to the display panel, and
wherein the coating layer overlaps with at least a portion of the driving voltage connection line.

9. The display device according to claim 8, further comprising a first area in which the touch driving connection line is disposed and a second area in which the data connection line and the driving voltage connection line are disposed.

10. The display device according to claim 1, further comprising:
a data driving circuit that supplies a data voltage;
a controller that controls the data driving circuit;
a bendable printed circuit board on which the controller is disposed;
a shield tape overlapping at least a portion of the support portion, the data driving circuit and the printed circuit board; and
a shield can overlapping the controller.

11. The display device according to claim 1, further comprising:
a cover glass that protects the display panel; and
a polarizing layer overlapping the cover glass,
wherein a first side surface of the coating layer is in contact with a side surface of the support portion, and
wherein a second side surface of the coating layer is in contact with a side surface of the polarizing layer.

12. The display device according to claim 11, further comprising an optical adhesive portion that attaches the cover glass and the polarizing layer, wherein a length of the optical adhesive portion is greater than a length of the polarizing layer.

13. The display device according to claim 12, further comprising a buffer portion disposed in an area where the polarizing layer, the optical adhesive portion and the coating layer are adjacent to each other.

14. The display device according to claim 11, further comprising:
a second substrate overlapping the polarizing layer; and
a second attachment portion overlapping the second substrate,
wherein the second attachment portion overlaps the first attachment portion and the support portion.

15. The display device according to claim 14, further comprising a first substrate disposed between the first attachment portion and the second attachment portion, wherein the first substrate overlaps the display panel.

16. The display device according to claim 15, further comprising a metal plate overlapping the second substrate and the display panel,
wherein the second attachment portion attaches the first substrate to the metal plate.

17. The display device according to claim 5, wherein the second coating layer partially overlaps with the first coating layer.

18. A flexible portion of a display device, comprising:
a flexible portion of a display panel including a plurality of sub-pixels;
a coating layer disposed on the portion of the display panel;
a support portion disposed on an edge portion of the display panel portion and directly interfacing with the coating layer along a thickness dimension;
a polarizing layer disposed on the coating layer, the polarizing layer being smaller in area than is the coating layer area;
a resin material disposed on the coating layer and adjacent to the polarizing layer;
a layer of optical clear adhesive disposed on and directly contacting both the polarizing layer and the resin material; and
a cover glass disposed on the optical clear adhesive.

19. A display device comprising a plurality of flexible portions according to claim 18.
